(19) United States
(12) Patent Application Publication
(10) Pub. No.: US 2008/0244354 A1
(43) Pub. Date: Oct. 2, 2008

(54) Apparatus and method for redundant multi-threading with recovery

(76) Inventors: Gansha Wu, Beijing (CN); Xin Zhou, Beijing (CN); Biao Chen, Beijing (CN); Jinzhan Peng, Beijing (CN); Peng Guo, Beijing (CN); Xiaogang Gou, Beijing (CN)

Correspondence Address: INTEL CORPORATION;c/o INTELLEVATE, LLC, P.O. BOX 52050, MINNEAPOLIS, MN, 55402, US

(21) Appl. No.: 11/729,187

(22) Filed: Mar. 28, 2007

(51) Int. Cl. H03M 13/45

(52) U.S. Cl. 714/755

(57) ABSTRACT

A method and apparatus for reducing the effect of soft errors in a computer system is provided. Soft errors are detected by combining software redundant threading and instruction duplication. Upon detection of a soft error, errors are recovered through the use of software check pointing/rollback technology. Reliable regions are identified by vulnerability profiling and redundant multi-threading is applied to the identified reliable regions.

### FIELD

This disclosure relates to detection of soft errors (or transient errors) and in particular to the use of redundant multi-threading for detecting and recovering from soft errors.

### BACKGROUND

A soft error involves a change to data and may be caused by random noise or signal integrity problems. Soft errors may occur in transmission lines, in logic, in magnetic storage or in semiconductor storage. These errors may be due to cosmic events in which alpha particles result in random memory bits changing state from a logical ‘0’ to a logical ‘1’ or from a logical ‘1’ to a logical ‘0’. The change of state may result in an operating system crash or incorrect data being stored in a memory cell. A soft error does not damage hardware; the only damage is to the data that is being processed.

With the continued decrease in the size of electronic components such as processors and chipsets, there has been an increase in the rate of soft errors. For example, the error rate for 16-nm processing technology is almost 100 times that of 180-nm processing technology.

### BRIEF DESCRIPTION OF THE DRAWINGS

Features of embodiments of the claimed subject matter will become apparent as the following detailed description proceeds, and upon reference to the drawings, in which like numerals depict like parts, and in which:

FIG. 1 is a block diagram of a system that includes an embodiment of a Software-implemented Redundant Multi-Threading with Recovery (RMT) translator and compiler according to the principles of the present invention;

FIG. 2 is a block diagram illustrating an infrastructure for an embodiment of a RMT translator to translate reliable regions identified in source code into reliable binary code;

FIGS. 3A-3B illustrates translation of an example of source code for a reliable region into reliable code with redundant threads;

FIG. 4 is a flow graph illustrating an embodiment of a method for recovering from soft errors in the reliable code with redundant threads shown in FIGS. 3A-3B; and

FIG. 5 illustrates an embodiment to ensure that the LT 302 and the TT 304 have the same view of the memory image.

Although the following Detailed Description will proceed with reference being made to illustrative embodiments of the claimed subject matter, many alternatives, modifications, and variations thereof will be apparent to those skilled in the art. Accordingly, it is intended that the claimed subject matter be viewed broadly, and be defined only as set forth in the accompanying claims.

### DETAILED DESCRIPTION

Many reliability methods have been proposed. One such method is redundant multi-threading that takes advantage of double or triple modular redundancy to detect or/and recover errors. For example, hardware Redundant Multi-Threading (RMT) leverages the hardware redundancy of a simultaneous multithreading (SMT) processor or a Chip-Level Multiprocessing (CMP) architecture processor, as well as hardware checkpoint, synchronization and validation mechanisms, to detect or recover errors. These hardware RMT mechanisms are software transparent, but at the expense of hardware complexity.

RMT solutions that achieve similar reliability and application transparency but require minimal hardware have been proposed, for example, Instrumented Redundant Multithreading. However, although instrumented redundant multithreading reduces the design complexity in the hardware pipeline, it still needs hardware checkpoint and speculation support.

Software Redundant Threading (SRT) is a pure software solution. However, although SRT can detect soft errors which may also be referred to a transient faults but SRT cannot recover from transient faults. A soft error refers to a hardware error which may alter voltage levels resulting in a temporary or transient error. Soft errors may be due to cosmic events in which alpha particles result in random memory bits changing state from a logical ‘0’ to a logical ‘1’ or from a logical ‘1’ to a logical ‘0’.

An embodiment of Redundant Multi-Threading (RMT) with Recovery according to the principles of the present invention both detects and recovers errors. Errors are detected by combining software redundant threading (SRT) and instruction duplication. Error recovery is performed through the use of software check pointing/rollback technology. In an embodiment, RMT is applied only to reliable regions identified by vulnerability profiling so as not to degrade system-wide performance. In one embodiment, RMT with recovery does not require any special hardware. In other embodiments, RMT with recovery may be accelerated through the use of special hardware.

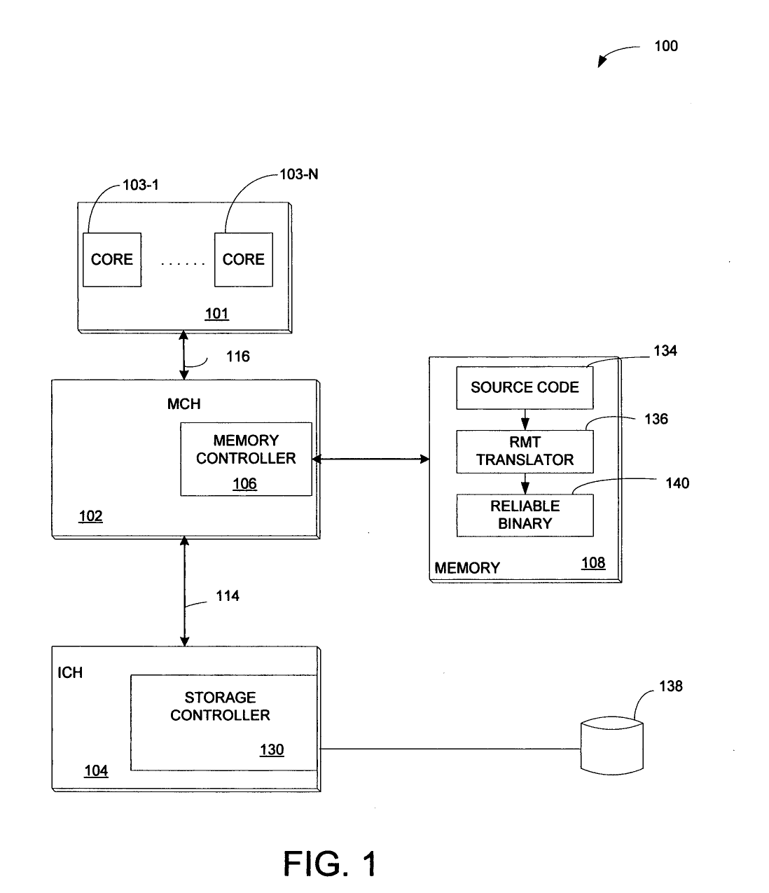

FIG. 1 is a block diagram of a system that includes an embodiment of a Software-implemented Redundant Multi-Threading (RMT) with Recovery translator and compiler according to the principles of the present invention. The system 100 includes a Central Processing Unit (CPU) 101, a Memory Controller Hub (MCH) or Graphics Memory Controller Hub (GMCH) 102 and an I/O Controller Hub (ICH) 104. The MCH 102 controls communication between the CPU 101 and memory 108.

The CPU 101 may include one or more processing cores 103-1, . . . , 103-N. The CPU 101 may be any one of a plurality of processors such as a single core Intel® Pentium IV® processor, a single core Intel Celeron processor, an ®XScale processor or a multi-core processor such as Intel® Pentium D, Intel® Xeon® processor, Intel® Core® Duo processor or Intel® Core 2 Duo® Conroe E6600 processor or any other processor.

The memory 108 may be Dynamic Random Access Memory (DRAM), Static Random Access Memory (SRAM), Synchronized Dynamic Random Access Memory (SDRAM), Double Data Rate 2 (DDR2) RAM or Rambus Dynamic Random Access Memory (RDRAM) or any other type of memory.

The ICH 104 may be coupled to the MCH 102 using a high speed chip-to-chip interconnect 114 such as Direct Media Interface (DMI). DMI supports 2 Gigabit/second concurrent transfer rates via two unidirectional lanes. The CPU 101 and MCH 102 communicate over a system bus 116. The ICH 104 may include a storage controller 130 for controlling communication with a storage device 138 coupled to the ICH 104.

As is well known in the art, source code 134 that may be stored in memory 106 or storage device 138 is compiled through the use of translators and compilers into binary code that is, a machine executable format. In one embodiment, the system includes a RMT translator 136 that translates reliable regions in source code 134 and compiles them into reliable binary code 140. The reliable regions in the source code 134 may be identified by vulnerability profiling.

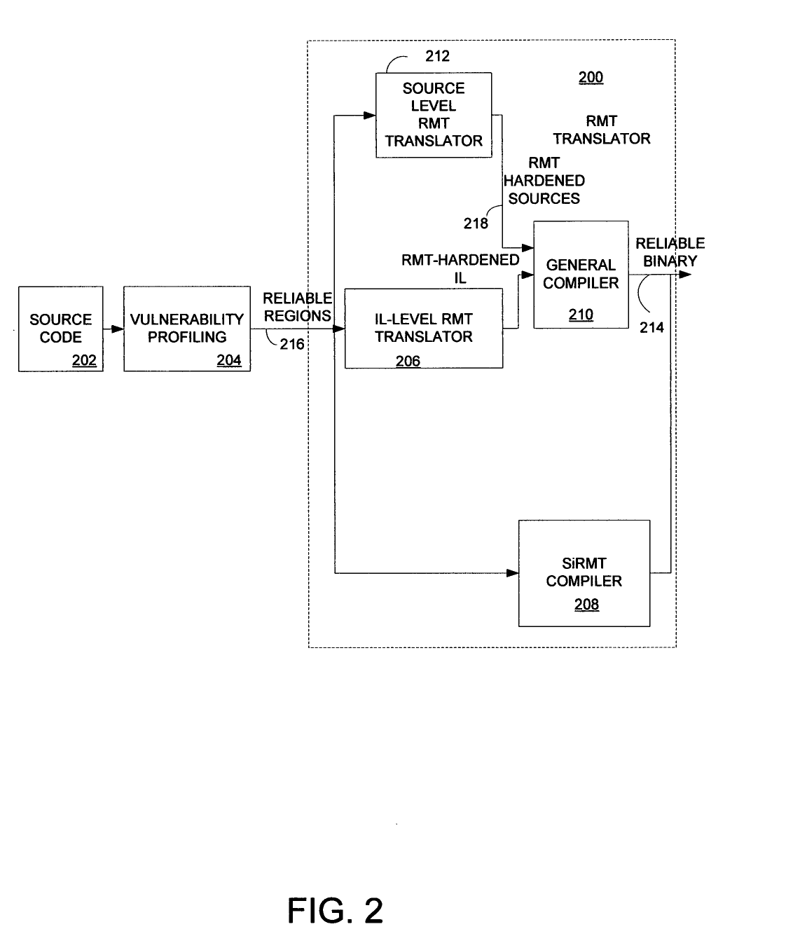

FIG. 2 is a block diagram illustrating an infrastructure for an embodiment of a RMT with recovery translator 136 that translates reliable regions identified in source code into reliable binary code. The high-level framework illustrates how components (modules) that may be stored in memory 108 (FIG. 1) or storage device 138 (FIG. 2) are interconnected.

Prior to converting the reliable regions in the source code 134 into reliable binary code 140, the source code 134 is reviewed in order to identify the reliable regions. In one embodiment, the reliable regions may be identified by vulnerability profiling 204. In another embodiment, the reliable regions may be identified by visual inspection by a software programmer.

Vulnerability profiling 204 uses either dynamic or static profiling techniques to identify reliable regions in the source code 134. Unlike profiling techniques that use timing information to identify performance bottlenecks, vulnerability profiling injects error campaigns into the program execution and collects error manifestation behaviors to identify reliability bottlenecks. The code regions enclosing these bottlenecks are transformed as reliable regions.

In another embodiment, reliable regions in the source code may be explicitly specified in the source code by a programmer based on an understanding of which parts of the source code need to be reliable. In an embodiment, RMT with recovery provides two language constructs: reliable regions or reliable variables.

A reliable region is a region in the source code that is enclosed by a reliable clause (construct), for example,

reliable {
...
}

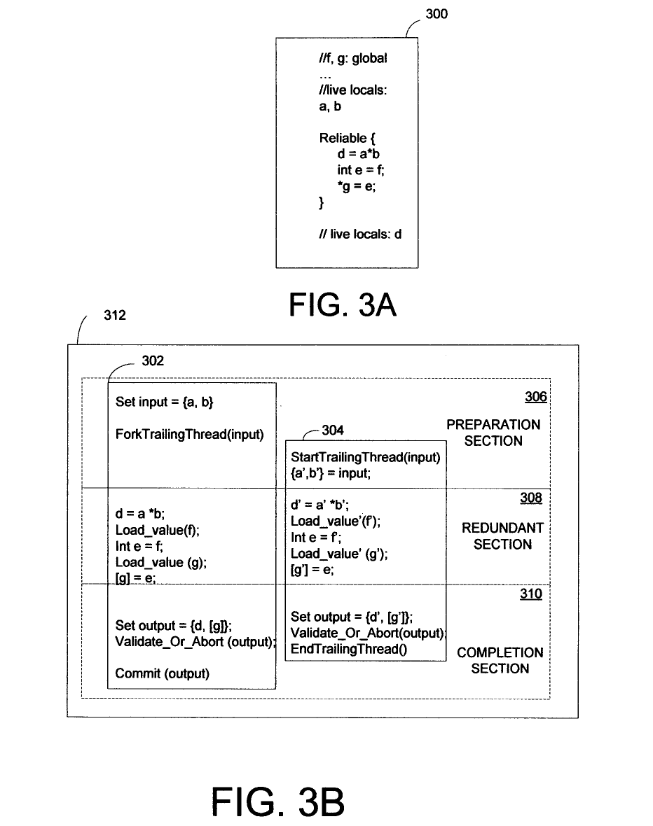

Upon detecting the reliable region construct, a RMT with recovery translator 200 hardens the enclosed code specifically with an embodiment of the RMT technique that will be described later in conjunction with FIGS. 3A-3B.

A reliable variable may be declared as follows:

reliable int*buffer;

Or alternatively, a reliable variable may be declared as an extension of an existing programming paradigm, for example:

(1) for Microsoft® platform compatibility:

_declspec(reliable) int*buffer;

(2) for GNU platform compatibility:

int*buffer_attribute_(reliable);

The semantic of the reliable variable is that the neighborhood code surrounding the use of the reliable variable is implicitly identified as a reliable region. If the reliable variable is extensively used, this avoids the need to specify these reliable regions explicitly everywhere in the source code. However, the size of the neighborhood surrounding the use of the reliable variable is dependent on the RMT with recovery translator 200. For example, if the reliable variable is used more than once in one basic block of source code, the RMT with recovery translator 200 may consider that the entire block is a reliable region as an optimization.

After the reliable regions 216 have been identified in the source code 202 either manually or through vulnerability profiling 204, the identified reliable regions 216 may be transformed into reliable binary 214 via one of three paths shown in FIG. 2.

On path 1, source-level RMT with recovery translator 212 translates reliable regions into RMT-hardened sources 218, which can be compiled into reliable binary via a general compiler 210. The RMT components, such as redundant threads and data structures (e.g. queues), are visible to the debugger at the source level, which makes debugging the application easier. Code optimality is not the concern of the RMT, but of the underlying general compiler 210. The source-level RMT with recovery translator 212 can leverage the rich features of high-level languages. For example, RMT can leverage_try { . . . }_catch or signal handling/longjmp to catch and rectify unexpected exceptions and abnormal control flow errors. However, the source level RMT translator 212 treats RMT operations as normal function calls. For example, an RMT operation may be a memory read which may be translated into a RMT routine call “rmt_read_mem( . . . ).

On path 2, RMT with recovery compiler 208 directly compiles the identified reliable regions into reliable binary 214. Path 2 has a unique advantage: a RMT-aware compiler 208 is more capable of aggressive optimizations. For example, a RMT-aware compiler 208 may perform aggressive optimizations across multiple RMT operations based on clear understanding of their semantics.

On path 3, an IL (Intermediate Language)-level RMT translator 206 translates the reliable regions into RMT-hardened IL, which can be compiled into reliable binary via general compiler(s) 210. Particularly, it is preferable if the IL is general enough to be targeted to multiple high-level languages and multiple architectures, for example, high-level languages such as C−− (C minus minus). Path 3 combines the advantages of both path 1 and path 3, that is, optimizations and leverages high-level languages.

The term “RMT with recovery translator” 200 is used to represent any of the three paths shown in FIG. 2 and will also be referred to as the “RMT translator”.

FIGS. 3A-3B illustrates translation of an example of source code for a reliable region 300 into reliable code 312 with redundant threading. FIG. 3A illustrates the source code for the reliable region 300. In this example, the reliable region is enclosed by a reliable clause (construct). The RMT translator 200 hardens the reliable region by applying redundant threading to the reliable region.

The RMT translator 200 described in conjunction with FIG. 1 analyzes the original source code for the reliable region 300 and applies redundant threading to the source code for the reliable region 300 into reliable code with redundant threading 312. The reliable region with redundant threading 312 achieves reliability by double modular redundancy from two threads (leading and trailing).

FIG. 3B illustrates a leading thread (LT) 302 and a trailing thread (TT) 304 for the reliable region with redundant threading 312. The LT 302 runs slightly faster than the TT 304.

The RMT translator 200 identifies live variable sets at the entry and exit of the reliable region in the source code 300 shown in FIG. 3A. Referring to FIG. 3A, the source code for the reliable region 300 has two global variables (f and g) and two local variables (a and b). An “input set” (for example, set input={a, b}) and an “output set” (for example, set output={d, [g]}) in the threads 302, 304 are populated based on local variables in the source code for the reliable region 300. As the local variables a and b are alive at the input, they are placed in the “input set” by the LT 302. In the reliable region, a local variable d and a global memory location g are assigned with new values. These values are alive at the exit of the reliable region 300 so they are placed in the output set.

The reliable region with redundant threading 312 may be subdivided into three sections: a preparation section 306, a redundant section 308 and a completion section 310.

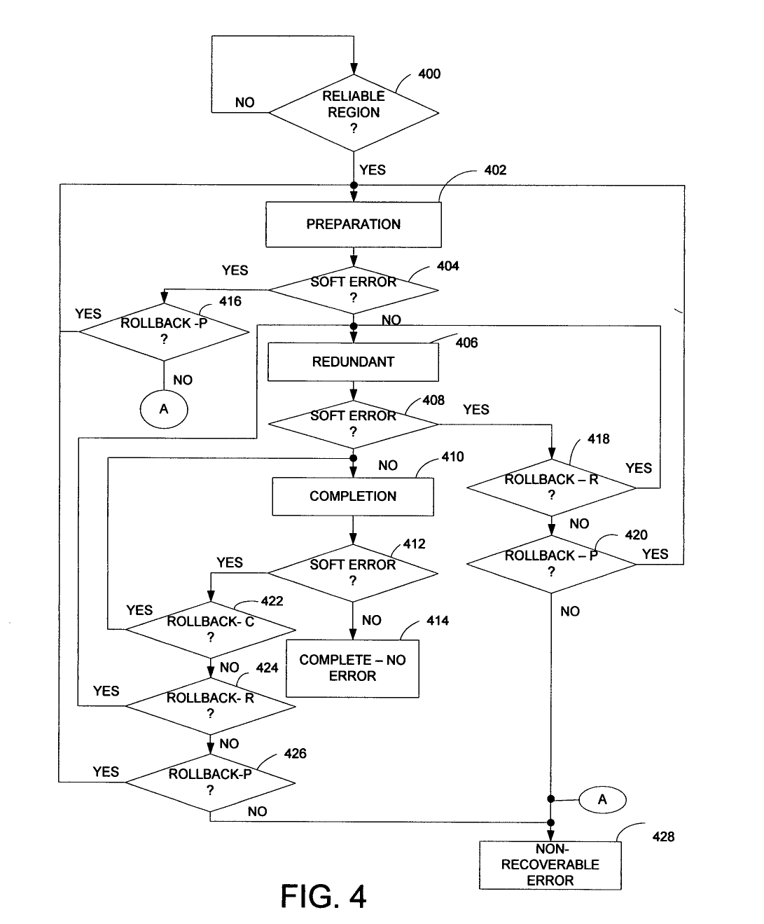

FIG. 4 is a flow graph illustrating an embodiment of a method for recovering from soft errors in the reliable code with redundant threads shown in FIGS. 3A-3B. FIG. 4 will be described in conjunction with FIGS. 3A-3B.

At block 400, upon detection of a reliable region in the source code 300, processing continues with block 402.

At block 402, in the preparation section 306 of the reliable region with redundant threading 312, the LT 302 constructs an input set (local variables a, b), forks a TT 304 and passes the input set to the TT 304. The TT 304 may be a new thread; or may be a thread leased from a thread pool, which is typically a more lightweight thread. The TT 304 initializes its state from the received input set, that is, the TT 304 initializes its mirror set of local variables (a and b). At this time point, both the LT 302 and the TT 304 finish their respective “Preparation Section” 306.

At block 404, if a soft error occurs while the LT 302 constructs the input set, both the LT 302 and the TT 304 will compute based on the wrong input set because errors in the input set are undetectable and unrecoverable. An instruction duplication technique may be used to further harden the binary code, that is, reduce sensitivity to soft errors. For example, if the input set involves the hashing computation:

```
retry:
    index = address % NUM_BUCKETS; //assume the variables,
address and buckets, are correct
    index′ = address % NUM_BUCKETS;
    if (index != index′) goto retry; //validate
    is_bucket_empty = buckets[index] == NULL;
    is_bucket_empty′ = buckets[index′] == NULL;
    if (is_bucket_empty != is_bucket_empty′) goto retry; //validate
    ... ...
```

This mechanism effectively complements Redundant Multi-Threading (RMT) with single thread time redundancy rather than thread redundancy.

If a soft error is detected at block 404 (through instruction duplication), processing continues with block 416. If not, processing continues with block 406.

If a soft (transient) error occurs while passing the input set to the TT 304 or when the TT 304 initializes its state from the input state received from the LT 302, the TT 304 generates results that are different from the results generated by the LT 302.

At block 406, in the redundant section 308, a local variable d and a global memory location g are assigned with new values. As the local variables d and [g] are alive at the exit of the reliable region they are placed in an “output set”. As the local variable e is not alive at the exit of the reliable region, it does not appear in the output set.

All modifications to an output set are either buffered or logged such that these modifications are revocable.

RMT with recovery may treat the loading of global variables differently in the LT 302 and the TT 304. For example, when loading the same global variable for example, [g] in the redundant section 308, the two threads may get different values if the two loads are interleaved with stores of the same variable from a third thread. In one embodiment in the redundant section 308, the two loads are performed by two different interfaces, namely load_value in LT 302 and load_value′ in TT 304. Practically there are many embodiments of the two interfaces.

In one embodiment, static analysis is used to identify all global variables/memory locations that are used in the reliable region. The LT 302 bulk-loads the values, puts them into the input set and replicates the input set to the TT 304, just as local variables. This mechanism is not applicable under some circumstances: for example, sometimes the global memory locations are not known at the entry of the region; or the values of some global memory locations are subject to changes for example, by other threads, during the execution of the region.

In another embodiment, the global variables are loaded directly. That is, the LT 302 and the TT 304 respectively load from the same memory location. However, this embodiment is very prone to roll back if there are other threads frequently writing the same location, because the LT 302 and the TT 304 very likely read different values from the location because they read the location at different times. Moreover, the LT 302 may also read-then-write the location and so the TT 304 reads the value written by the LT 302 which is not the same as the value read by the LT 302.

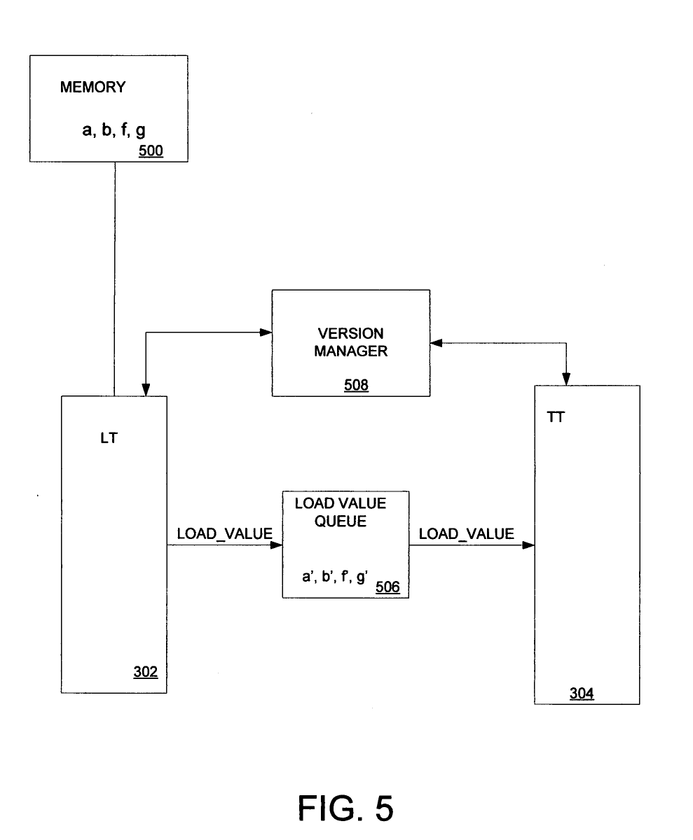

FIG. 5 illustrates an embodiment to ensure that the LT 302 and the TT 304 have the same view of the memory image. In order to support rollback, a version manager 508 buffers or logs all modifications to an output set.

The LT 302 loads the values of global variables directly from memory 500 and meanwhile enqueues them into a load value queue (LVQ) 506. The TT 304 dequeues the values from the LVQ 506, instead of reading from memory 500 directly. In this embodiment, the LT 302 and the TT 304 consistently see the same memory image in the LVQ 506. The LVQ 506 can be a simple FIFO queue, if the LT 302 and the TT 304 ensure that they access a series of memory locations in the same order. For example, if the LT 302 and TT 304 execute on in-order processors or processors ensuring load order. If that is not the case, for example, the underlying processor reorders memory loads, the LVQ 506 may be a Content Addressable Memory (CAM) for example, a cache-like array or a hash table from which the TT 304 gets the values based on the memory locations rather than the indices. Of the three embodiments discussed for loading the global values, the LVQ embodiment is the slowest one, because of the inherent inter-thread communication/synchronization overhead between the producer thread (LT 302) and consumer thread (TT 304). In an embodiment of an optimized implementation of LVQ, a decoupled queue is used to minimize inter-thread communication overhead. Both the LT 302 and the TT 304 maintain a respective local buffer: the LT 302 loads values into the LT local buffer; the TT loads values from the TT local buffer; when the LT buffer overflows or the TT buffer underflows, LT 302 bulk-copies all values in the LT local buffer to the TT local buffer.

In another embodiment a combination of the methods used in the above three embodiments may be used in order to achieve best trade-off between performance and applicability.

Returning to FIG. 4, at block 408, if a soft error occurs in the redundant section, processing continues with block 418. If not, processing continues with block 410.

At block 410, the completion section 310 (FIG. 3B) includes the validation point in both the LT 302 and the TT 304 and the commit point only in the LT 302. The validation point (Validate-Or-Abort) is where the LT 302 and the TT 304 compare respective current output sets and trigger rollback if they differ. The TT 302 and the LT 304 are lock-stepped at the Validate-Or-Abort points. In the completion section 310, both the LT 302 and the TT 304 reach the validation point in which the output sets of the two threads (LT 302, TT 304) are compared. If validation fails because the output sets differ, the execution is aborted and rolled back to the beginning of the Redundant Section 308 and the modifications to the output set are abandoned. If the validation is successful, the values in the output set are committed and become permanent.

The validation (Validate-Or-Abort) in the LT 302 and the TT 304 in the completion section 310 involves inter-thread synchronization and data communication. The inter-thread synchronization may be implemented using the underlying platform's hardware features (such as Intel® Architecture's (IA) MWAIT) or software features (for example, operating system wait primitives). The data communication is typically based on a queue-like producer/consumer model. The commit point concludes the completion section 310.

At block 412, if a soft error occurs in the completion section, processing continues with block 422. If not, processing is complete.

At block 414, execution of the reliable region is complete with no errors, that is, no errors were detected or any detected errors were recoverable. Results are committed.

At block 416, in order to recover from a soft error, a counter maintained by the Validate-Or-Abort function is incremented to record the number of occurrences of a LT 302 and TT 304 rollback to try to attempt to correct the soft error. If the counter is below a selectable number of rollbacks, the error may be recoverable and processing continues at block 402 at the beginning of the preparation section. If the error is not corrected after a selectable number of rollbacks, then the error is a permanent rather than a transient error (soft error) and is therefore not recoverable. Processing continues with block 428 to report the non-recoverable error.

At block 418, in order to recover from a soft error, a counter maintained by the Validate-Or-Abort function is incremented to record the number of occurrences of a LT 302 and TT 304 rollback to try to attempt to correct the soft error. If the value of the counter is at or below a threshold value, the soft error may be recoverable, and execution is rolled back to block 406 to the beginning of the redundant section. If the counter is below a selectable number of rollbacks, the error may be recoverable and processing continues at the beginning of the redundant section. If not, processing continues with block 420.

At block 420, if the counter value exceeds the threshold value, for example, in one embodiment, the threshold may be set to 3, the execution is further rolled back to the beginning of the Preparation Section 306, rather than the beginning of Redundant Section 308. If the error is not corrected after a selectable number of rollbacks, then the error is a permanent rather than a transient error (soft error) and is therefore not recoverable. Processing continues with block 428 to report the non-recoverable error.

At block 422, if an error occurs in the completion section and the number of errors is below the threshold, processing continues at block 410 at the beginning of the completion section. If not, processing continues with block 424.

At block 424, if an error occurs in the completion section and the number of errors is below a selectable number, processing is rolled back to the beginning of the redundant section at block 406. If not, processing continues with block 426.

At block 426, if an error occurs in the completion section 310 and the number of errors is below a selectable number that indicates a rollback to the preparation section, processing continues with block 402. If the number of errors is above a threshold number, the error is not recoverable and processing continues with block 428 to report the non-recoverable error. In another embodiment, blocks 416, 218, 420, 424 and 426 may be consolidated into a single “rollback” block, to process a soft error that occurs in any of the sections 306, 308, 310.

At block 428, the non-recoverable error is reported. Processing is complete.

In order to support rollback, the version manager 508 keeps old versions (checkpoints) of states. Software buffering and logging are two known version managers that are deployed in software transactional memory and software speculative computation: software buffering buffers every memory write, software logging logs every write when it writes to a physical memory location.

In software buffering, buffered memory writes are invisible to other threads until they are committed to their physical memory locations. In this regard, the memory image before it is committed is a checkpoint. It is relatively easy to rollback to the checkpoint by just discarding the buffered writes.

In software logging, the old values that are stored in physical memory locations in physical memory, for example, memory 108 (FIG. 1) are saved and the new values are visible to other threads immediately. To rollback, the saved old values are restored to their relative physical memory locations.

The buffering mechanism involves a store buffer. In an embodiment, the store buffer works like a software cache indexed by the write addresses. Each write address has only the latest version of the value stored in the cache. Meanwhile, the store buffer also serves the loads of global values for read-after-write cases. The buffering technique works well with the LVQ technique.

The logging mechanism employs a list of old values in memory. Each entry in the list corresponds to a write in the store order. Each write address may have one or multiple versions of its old values logged, and with the latest version updated “in place” in the memory. The logging technique allows global values to be loaded directly into memory. In this regard, the logging technique is faster than the buffering mechanism.

An embodiment of checkpoint/versioning that uses the logging mechanism in conjunction with the direct value loading mechanism may be slower if the memory locations to be loaded are prone to frequent updates because the LT 302 and the TT 304 may be likely to see different values. For example, after the LT 302 loads a value in a memory location, the same memory location may be updated by some other application threads before the TT 304 loads the value. Eventually the LT 302 and the TT 304 will fail in the completion section 310 which will result in a roll back to the redundant section 308. If this kind of rollback occurs frequently, the system-wide performance may be reduced. In this situation, more validation points may be inserted in the reliable region 300 in addition to the validation point in the completion section 310 of the reliable region such that the validation failure can be detected earlier with less wasted LT/TT computation time based on detection of different values.

In an embodiment with buffering, the output set is committed to the memory, and the modified states are made visible to other threads. Unlike a software transactional memory, the commit operation does not need to be atomic. In the logging embodiment, the commit process is trivial because the memory already has the latest versions of modified states.

In another embodiment, the amount of memory for storing states may be reduced through the addition of multiple validation points in the reliable region 300. If the reliable region 300 has a large modified set, the data structure to hold the modified states, that is, the store buffer or list needs to be large or be extendable. This is a considerable burden to memory footprint and implementation complexity which can be reduced through the addition of multiple validation points. The number of validation points may be selected to reduce memory consumption while balancing the additional inter-thread communication overhead so as not to seriously affect the performance.

The frequency of the validation points may be determined by a cost model from static analysis/profiling, which takes performance, buffer size and other factors into account. In the extreme case, RMT performs validation for each write.

In yet another embodiment, a reliable region 302 may have multiple commit points to sub-divide the reliable region into multiple reliable sub-regions. Multiple commit points are useful, for example, to commit when the output set overflows, to commit when other threads need to see latest modifications, for example, other threads wait on some volatile variables or to commit when an external function call is encountered. Each commit point commits all the validated values and clears the output set.

A commit point marks the completion of a reliable sub-region in the reliable region and starts a new reliable region. Next time when rollback occurs, the execution flow and state are reverted to the beginning of current sub-region instead of the entire reliable region.

Validation points and commit points may be coupled in a 1:1 fashion or decoupled. In the example shown in FIGS. 3A-3B, the validation point and commit point are coupled in a 1:1 fashion as there is only one output set which is to be validated and committed at the next validation/commit point. Validation points and commit points may be decoupled, for example, there may be multiple validation points between two commit points with a validation point immediately before the next commit point to validate all the values to be committed. This requires the two output sets: one that is already validated; the other that is yet to be validated.

RMT generates a specialized version of a function call in the reliable region. The specialized version of a function is only called in a reliable context. The specialized version of the function performs software check pointing and includes validation/commit points to guarantee reliable execution of the function as discussed in conjunction with the example of the reliable region 302 discussed in conjunction with FIGS. 3A-3B.

Typically, RMT passes the reliable context (including the output set) to the specialized version of the function as a parameter. Alternatively, the specialized version of the function may take the context from the thread local storage.

RMT may also insert a validation/commit point before the function call such that the specialized version of the function itself becomes a new sub-region. When a transient error is detected in the execution of the specialized version of the function, there is a rollback to the beginning of the specialized version of the function.

A transient error may also result in an operating system crash or in a deadlock condition. An operating system crash may occur as a result of incorrect computation of a memory address or a branch target. For example, a single bit flip change of state from one logical value to another logical value may change a stack address in an application level program into a kernel address. A subsequent access to the kernel address typically results in segment fault or general protection fault. Another example of a transient error that may result in an operating system crash is if there is single bit error in a branch instruction that could directs the control flow to data sections, inaccessible code regions or the middle of an instruction.

In order to handle an operating system crash due to transient errors (soft errors), the redundant section is wrapped with crash handlers. In an embodiment for the Microsoft Windows operating system, the Structured Exception Handling (SHE), that is, using_try { . . . }_catch construct, may be used to detect an operating crash and rollback to a point in the function prior to the operating system crash. In an embodiment for a Unix-like operating system, for example, Linux, a signal handler for SIGSEGV is registered and rollback is performed in the signal handler. The SEH and the signal handler may be intercepted or overwritten by user-provided counterparts in the reliable region. An example is shown below in Table 2:

TABLE 2

```
    _try { //RMT _try to start the reliable region
        ... ...
        _try { //user _try originally in the application
        code
... ... // if error occurs here, the user crash handler is invoked
        first
        } _catch (...) { //user crash handler
            ... ...
        }
        ... ...
} _catch (...) { //RMT crash handler
        ... ...
}
```

If the operating system crash is caused by an error in an application/user level program instead of a transient (soft) error, the user crash handlers are called in both threads, that is, LT 302 and the TT 304. Thus, both threads LT 302, TT 304 have the same execution path. If the operating system crash is caused by a transient (soft) error, only one thread for example, LT 302 activates the user crash handler. If the user crash handler does not relay the error to the RMT crash handler, eventually LT and TT will fail at validation points and trigger rollback. If the user handler relays the error to the RMT crash handler, the RMT crash handler in the LT 302 and the TT 304 performs the rollback.

In addition to an operating system crash, a soft error may also introduce a deadlock condition. For example, a soft error may result in one of the following deadlock conditions: a loop condition becomes true forever; a branch target improperly points to the branch instruction itself; a thread continues to wait because the wakeup is missed due to incorrect control flow.

In order to handle a deadlock condition due to a soft error, a wait primitive at the validation point is associated with a timeout value. The timeout value is selected based on the frequency of validation points in the reliable region 300, that is, whether there are one or more validation points. A timeout handler rolls back the execution of the TT 304 and LT 306 allowing recovery from the soft error.

A reliable region 302 may include a call to an external function such as a library call, for example, a libc or a system call. However, the source code for external functions is not visible to RMT 200. Thus, the source code cannot be modified by RMT 200. In one embodiment, in order to recover from a soft error that occurs while executing an external function, the RMT 200 may use a binary translator to translate the function. If the caller of an external function is a RMT transformable function, the RMT transforms the call to the external function to a binary translator stub. The binary translator stub may intercept the call to the function if it has not been translated yet. The binary translator translates the binary into RMT recognizable intermediate representation (IR) and performs RMT transformation on the IR. If the function calls another external function, that external call is also directed to a binary translator stubs. If the function calls a RMT transformable function, the call to the RMT transformable function is directed to the function's RMT transformed code.

In another embodiment, the external function is not transformed. Instead, the LT performs early validation/commit before the call to an external function. Then, the LT schedules the execution of the function to more reliable processors and waits for the result. Meanwhile, the TT waits for the result. When the result of the function is returned, the LT resumes its execution with a new reliable sub-region. The result of the function is also passed to the TT to resume its execution. This embodiment is preferable if the system is heterogeneous multi-core with different reliabilities. For example, a reliable but slower core may be assigned to run the host operating system code (including the external functions), and less reliable but faster cores may be assigned to run the application code transformed by RMT. The partition of the host operating system code and the application code results in improved system-wide reliability.

An error in the operating system code affects the whole system, while an error in application code only affects one application in the worst case. Thus, in a multi-core system, an operating system may run on a reliable core, and RMT may be used to harden application code to run on less reliable cores. This configuration may improve the overall system reliability significantly with minimal hardware investments on reliability.

The RMT transformed code for some reliable regions may slow down the execution time by a factor of 1.5-4. However, because the execution of the reliable regions attribute to only <10% of the total execution time, the system-wide performance degradation is only 1-34%.

RMT 200 may run directly on a multi-core CPU 101, based on the software based infrastructure. However, RMT 200 may be accelerated through leveraging hardware enhancements in order to minimize the performance overhead from the inter-thread communication (LT-TT) and software check pointing (validation).

In one embodiment, there may be fast communication between some cores 103-1, . . . , 103-N. For example, there may be a non-uniform core interconnect that enables fast communication between some designated cores 103-1, . . . 103-N or communication latency between adjacent cores on a ring-based interconnect network may be low. To take advantage of the hardware enhancements, the LT and TT may be scheduled on two cores 103-1, . . . , 103-N that may be connected with wider bandwidth or smaller latency. If the interconnect is also reliable, the vulnerabilities from communication may be removed.

In another embodiment, fast inter-core communication may be enabled through the use of a mailbox or memory-mapped registers which may be mapped to RMT queues. Speculative execution or transactional memory may be used by RMT to provide the check pointing/rollback capability in the redundant execution.

RMT may be tuned to leverage heterogeneous multi-cores with different reliabilities. For example, some cores may be reliable cores and others may be unreliable. The unreliable cores may rely on RMT to achieve overall reliability. RMT may be carefully tuned to leverage the heterogeneity. For example, when there is a call to an external function, the RMT may migrate the execution of the external function to a reliable core. RMT may migrate performance-critical computations in the reliable regions to the reliable cores to achieve the best system-wide performance. The RMT may take a dynamic approach to map computations to cores with different reliabilities. For example, a thread may be reassigned to a more reliable core when multiple rollbacks have been detected. Some cores may have different levels of reliability, for example, one core may have a more reliable Arithmetic Logical Unit (ALU) and less reliable memory. The vulnerability profiling takes this heterogeneity into account.

It will be apparent to those of ordinary skill in the art that methods involved in embodiments of the present invention may be embodied in a computer program product that includes a computer usable medium. For example, such a computer usable medium may consist of a read only memory device, such as a Compact Disk Read Only Memory (CD ROM) disk or conventional ROM devices, or a computer diskette, having a computer readable program code stored thereon.

While embodiments of the invention have been particularly shown and described with references to embodiments thereof, it will be understood by those skilled in the art that various changes in form and details may be made therein without departing from the scope of embodiments of the invention encompassed by the appended claims.

1. A method comprising:
applying redundant threading to a reliable region; and
upon detecting a soft error, recovering from the soft error by performing check pointing to rollback to a point in the reliable region prior to the detection of the soft error.

2. The method of claim 1, wherein applying further comprises:
replicating the reliable region into two communicating threads, a leading thread and a trailing thread;
repeating, by the trailing thread, computations performed by the leading thread during execution of the reliable region.

3. The method of claim 2, further comprising:
comparing results computed by the leading thread and the trailing thread; and
detecting the soft error if at least one non-matching result is detected.

4. The method of claim 2, wherein the reliable region includes a plurality of sub-regions and the results are compared at the end of each sub-region.

5. The method of claim 4, further comprising:
upon detecting no soft error in a sub-region, committing the results at the end of the sub-region.

6. The method of claim 4, wherein upon detecting a soft error in a sub-region, performing check pointing to rollback to a point in the sub-region prior to the detection of the soft error.

7. The method of claim 2, wherein modifications to an output set by the threads are stored in a buffer.

8. The method of claim 2, wherein modifications to an output set by the threads are logged.

9. An apparatus comprising:
a Redundant Multi-Threading (RMT) with Recovery translator to apply redundant threading to a reliable region to generate redundant threads for the reliable region, upon detecting a soft error, the redundant threads for the reliable region to recover from the soft error by performing check pointing to rollback to a point in the reliable region prior to the detection of the soft error.

10. The apparatus of claim 9, wherein the redundant threads comprise:
a leading thread; and
a trailing thread, the leading thread and trailing thread to communicate with each other and the trailing thread to repeat computations performed by the leading thread during execution of the reliable region.

11. The apparatus of claim 10, wherein the soft error is detected if at least one non-matching result is detected based on a comparison of results computed by the leading thread and the trailing thread.

12. The apparatus of claim 10, wherein the reliable region includes a plurality of sub-regions and the results are compared at the end of each sub-region.

13. The apparatus of claim 12, wherein results are committed at the end of a sub-region upon detecting no soft error in the sub-region.

14. The apparatus of claim 12, wherein upon detecting a soft error in a sub-region, to perform check pointing to rollback to a point in the sub-region prior to the detection of the soft error.

15. The apparatus of claim 10, further comprising:
a buffer to store modifications to an output set by the threads.

16. The apparatus of claim 10, wherein modifications to an output set by the threads are logged.

17. An article including a machine-accessible medium having associated information, wherein the information, when accessed, results in a machine performing:
applying redundant threading to a reliable region; and
upon detecting a soft error, recovering from the soft error by performing check pointing to rollback to a point in the reliable region prior to the detection of the soft error.

18. The article of claim 17, wherein applying further comprises:
replicating the reliable region into two communicating threads, a leading thread and a trailing thread;
repeating, by the trailing thread, computations performed by the leading thread during execution of the reliable region.

19. The article of claim 18, further comprising:
comparing results computed by the leading thread and the trailing thread; and
detecting the soft error if at least one non-matching result is detected.

20. The article of claim 19, wherein the reliable region includes a plurality of sub-regions and the results are compared at the end of each sub-region.
